(19) United States
(12) Patent Application Publication
(10) Pub. No.: US 2013/0234198 A1
(43) Pub. Date: Sep. 12, 2013

(54) Electrical Circuit Protection Design with Dielectrically-Isolated Diode Configuration and Architecture

(71) Applicants: Moiz Khambaty, Santa Clara, CA (US); David Burgess, Santa Clara, CA (US); Vallangiman V. Srinivasan, San Francisco, CA (US)

(72) Inventors: Moiz Khambaty, Santa Clara, CA (US); David Burgess, Santa Clara, CA (US); Vallangiman V. Srinivasan, San Francisco, CA (US)

(73) Assignee: Manufacturing Networks Incorporated (MNI), Santa Clara, CA (US)

(21) Appl. No.: 13/413,621

(22) Filed: Mar. 6, 2012

(51) Int. Cl. H01L 29/88; H01L 29/861

(52) U.S. Cl. 257/106; 257/508; 257/E29.339; 257/E29.328

(57) ABSTRACT

A novel electrical circuit protection design with dielectrically-isolated diode configuration and architecture is disclosed. In one embodiment of the invention, a plurality of diodes connected in series is monolithically integrated in a single piece of semiconductor substrates by utilizing dielectrically-isolated trenching and silicon-on-insulator substrates, which enable formation of “silicon islands” to insulate a diode structure electrically from adjacent structures. In one embodiment of the invention, the plurality of diodes connected in series includes at least one Zener diode, which provides a clamping voltage approximately equal to its breakdown voltage value in case of a voltage spike or a power surge event. In another embodiment of the invention, the plurality of diodes connected in series includes a scalable number of monolithically-integrated forward-bias PN diodes, wherein the summation of the forward-bias voltage of each PN diode is equivalent to a net clamping voltage value for an electrical circuit protection design.

### BACKGROUND OF THE INVENTION

The present invention generally relates to power protection semiconductor designs for electrical devices. More specifically, the invention relates to one or more embodiments of electrical circuit protection designs with dielectrically-isolated diode configuration and architecture. Furthermore, the invention also relates to using a Zener diode or a scalable number of forward-bias diodes monolithically in series as a voltage clamp in an electrical circuit protection design.

Many electrical devices today operate in environments susceptible to unwanted and dangerous power surges or accidental reverse polarity input connections. If power surges (e.g. a voltage surge, a current surge, or both) are sufficiently high or prolonged beyond a negligible duration, electrical devices subject to power surges can sustain operation failure or permanent damages. Therefore, protection against power surges have been commonly addressed by transient voltage suppression (TVS) circuits, which protect integrated circuits (IC's) from accidental or undesirable high voltage spikes on the IC's.

Examples of TVS circuits include electrostatic discharge (ESD) protection diodes. Conventional TVS protection circuits comprise two or more diodes, at least one of which is designed to conduct electricity temporarily in case of a high-voltage surge event. TVS circuits are typically designed to clamp the voltage to a particular voltage value during a power surge event, and are also designed to endure an accompanying current surge through the TVC circuits, thereby protecting the load which comprises integrated circuitry requiring protection from power surges.

In general, diodes used in the TVS circuits must be large enough to handle large electrical currents produced in high-voltage surge events. Unfortunately, a large size of a diode typically creates a large load capacitance, which is unsuitable for some of the recent electronic systems which operate at high frequencies ranging from 100MHz to several GHz. For example, high junction capacitances in conventional TVC circuits generally adversely impact rapid ESD absorptions or other rapid protection requirements against power surge events.

Even though it is theoretically possible to reduce the junction capacitances of the diodes in TVS circuits by connection several diodes (i.e. N-number of diodes) in series to distribute and reduce the capacitance of each diode by the factor of 1/N, such a series-diode connection has not been feasible in monolithic IC's due to implementation difficulties. For example, because diodes built on a single semiconductor substrate (e.g. a monolithic chip) have a common anode per semiconductor substrate, series connections were impossible or impractical. Furthermore, although it may be theoretically possible to come up with a substrate structure with discrete diodes connected in series as an attempt to achieve distributed capacitances among diodes for the TVS circuits, a high cost of production, a large active area size, and an undesirable capacitive loading resulting in response bandwidth reduction make the series-connection discrete diode design impractical in most cases.

Therefore, it may be advantageous to devise a novel semiconductor structure and a related design, which enable scalable series diode connections in a monolithic chip, wherein the monolithic chip provides electrical circuit protection with low and/or distributed junction capacitances. Furthermore, it may be advantageous to devise a novel semiconductor structure and a related design, which provide durable and rapid protections against power surge events. In addition, it may also be advantageous to devise a novel semiconductor structure and a related design that reduce active area for junction capacitance reduction and miniaturization of power protection circuits.

### SUMMARY

Summary and Abstract summarize some aspects of the present invention.

Simplifications or omissions may have been made to avoid obscuring the purpose of the Summary or the Abstract. These simplifications or omissions are not intended to limit the scope of the present invention.

In one embodiment of the invention, an electrical circuit protection device incorporating diodes in a single piece of semiconductor substrates is disclosed. This electrical circuit protection device comprises: a bottom substrate layer; a bonding oxide layer electrically insulating the bottom substrate layer from the semiconductor substrates positioned above the bonding oxide layer; the semiconductor substrates comprising one or more silicon islands, wherein each silicon island is electrically insulated by one or more dielectrically-isolated sidewalls and the bonding oxide layer on a bottom surface of each silicon island; the one or more silicon islands, each of which containing an N-type bulk substrate and one or more silicon wells forming a PN diode and/or a Zener diode in each silicon island; one or more metal interconnects physically contacting the one or more silicon wells to provide one or more monolithic series connections among the diodes; and one or more oxide strips underneath the one or more metal interconnects to provide necessary electrical insulation between the one or more metal interconnects and the semiconductor substrates outside of physical contact regions.

In another embodiment of the invention, an electrical circuit protection device incorporating diodes in a single piece of semiconductor substrates is disclosed. This electrical circuit protection device comprises: a bottom substrate layer; a bonding oxide layer electrically insulating the bottom substrate layer from the semiconductor substrates positioned above the bonding oxide layer; the semiconductor substrates comprising one or more silicon islands, wherein each silicon island is electrically insulated by one or more dielectrically-isolated sidewalls and the bonding oxide layer on a bottom surface of each silicon island; the one or more silicon islands, each of which containing an N-type bulk substrate and a doped P+ well to form at least one forward-bias PN diode per silicon island, wherein a plurality of forward-bias PN diodes formed by the one or more silicon islands is monolithically connected in series using one or more metal interconnects; the one or more metal interconnects, each of which physically contacting a first region of the one or more silicon islands and a second region of the one or more silicon islands to provide one or more monolithic series connections among the diodes; and one or more oxide strips underneath the one or more metal interconnects to provide necessary electrical insulation between the one or more metal interconnects and the semiconductor substrates outside of physical contact regions.

### BRIEF DESCRIPTION OF DRAWINGS

FIG. 1 shows a cross section of a dielectrically-isolated (DI) and silicon-on-insulator (SOI) electrical circuit protection chip structure with a Zener diode and steering diodes connected monolithically in series, in accordance with an embodiment of the invention.

FIG. 2 shows a circuit diagram with a Zener diode and steering diodes connected in series, which correspond to the novel electrical circuit protection chip structure of FIG. 1, in accordance with an embodiment of the invention.

FIG. 3 shows a cross section of a dielectrically-isolated (DI) and silicon-on-insulator (SOI) electrical circuit protection chip structure with a Schottky diode, a PN diode, and a Zener diode connected monolithically in series, in accordance with an embodiment of the invention.

FIG. 4 shows a circuit diagram with a Schottky diode, a PN diode, and a

Zener diode connected in series, which correspond to the novel electrical circuit protection chip structure of FIG. 3, in accordance with an embodiment of the invention.

FIG. 5 shows a cross section of a dielectrically-isolated (DI) and silicon-on-insulator (SOI) chip structure with a Zener diode and a top-surface heat sink, in accordance with an embodiment of the invention.

FIG. 6 shows a cross section of a dielectrically-isolated (DI) and silicon-on-insulator (SOI) electrical protection chip structure with a scalable number of PN diodes connected monolithically in series, in accordance with an embodiment of the invention.

FIG. 7 shows a circuit diagram with two forward-bias PN diodes connected in series and a reverse-polarity protection PN diode, in accordance with an embodiment of the invention.

FIG. 8 shows a circuit diagram with four forward-bias PN diodes connected in series and a reverse-polarity protection PN diode, in accordance with an embodiment of the invention.

FIG. 9 shows a circuit diagram for a multi-channel electrical protection configuration with a Zener diode and multiple sets of steering diodes connected in series, in accordance with an embodiment of the invention.

FIG. 10 shows a circuit diagram for a multi-channel electrical protection configuration with a plurality of forward-bias PN diodes connected in series and a reverse-polarity protection PN diode, in accordance with an embodiment of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

The detailed description is presented largely in terms of description of shapes, configurations, and/or other symbolic representations that directly or indirectly resemble a novel chip structure for an electrical circuit protection design with dielectrically-isolated diode configuration and architecture. These descriptions and representations are the means used by those experienced or skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment. Furthermore, separate or alternative embodiments are not necessarily mutually exclusive of other embodiments. Moreover, the order of blocks in process flowcharts or diagrams representing one or more embodiments of the invention do not inherently indicate any particular order nor imply any limitations in the invention.

For the purpose of describing the invention, a term “monolithic” or “monolithically” is defined as being integrated, associated, and/or characterized on a single piece of chip or a chip substrate. For example, a plurality of diodes which are integrated “monolithically” on a silicon substrate means that the plurality of diodes are integrated on a single-piece silicon substrate.

In addition, for the purpose of describing the invention, a term “power surge” or “power surge event” is defined as a spike in voltage, current, or both. An example of a power surge is a voltage or current spike at an input terminal of an electrical device caused by an external power source, an external electrical signal, or a sudden change in environment such as lightening or storm.

Moreover, for the purpose of describing the invention, a term “silicon-on-insulator” or SOL is defined as a chip structure which has a semiconductor material (e.g. silicon) layer on top of an electrically-insulating layer (e.g. a silicon oxide layer or another electrically-insulating material layer).

Furthermore, for the purpose of describing the invention, a term “dielectrically isolated trench” (DI trench) is defined as a lateral electrical insulation of a first set of semiconductor substrate(s) from a second set of semiconductor substrate(s), which is separated by the DI trench.

In addition, for the purpose of describing the invention, a term “output voltage clamping” is defined as an ability to clamp an output voltage to a clamping voltage value at an output terminal of a power protection circuit to protect an electrical device connected to the output terminal of the power protection circuit, if an unwanted and/or dangerous voltage surge is detected. In one embodiment of the invention, the output voltage clamp is a Zener diode which is monolithically integrated into a single piece of semiconductor material along with steering PN diodes, wherein the Zener diode and each of the PN diodes are dielectrically isolated from each other to minimize undesirable parasitic junction capacitance and leakage currents. In the preferred embodiment of the invention, a Zener voltage, or a Zener breakdown voltage, of the Zener diode is the clamping voltage value. In another embodiment of the invention, the output voltage clamp is a compound device that performs a voltage clamping function. If the compound device is the output voltage clamp instead of a Zener diode, one advantage may be having a less current leakage than a typical Zener diode in a low Zener voltage application (e.g. Vz<5.6V). Yet in another embodiment of the invention, an effective output voltage clamp is determined by a total scalable number of forward-bias PN diodes connected monolithically in series, wherein each of the forward-bias PN diodes carry a distributed portion of the effective output voltage clamp.

One aspect of an embodiment of the present invention is providing a novel electrical circuit protection design with dielectrically-isolated diode configuration and architecture.

Another aspect of an embodiment of the present invention is providing a monolithic chip structure, which utilizes SOI and DI trenching to integrate PN diodes, Zener diodes, and/or Schottky diodes monolithically in series for providing a rapid, durable, and scalable voltage clamping to an electrical load.

Yet another aspect of an embodiment of the present invention is providing a small-footprint, energy-efficient, fast-acting, and monolithically-integrated novel power protection chip structure and a related circuitry comprising a Zener diode and one or more steering diodes.

In addition, another aspect of an embodiment of the present invention is providing a small-footprint, energy-efficient, fast-acting, and monolithically-integrated novel power protection chip structure and a related circuitry comprising a scalable number of forward-bias PN diodes and a reverse-polarity protection diode.

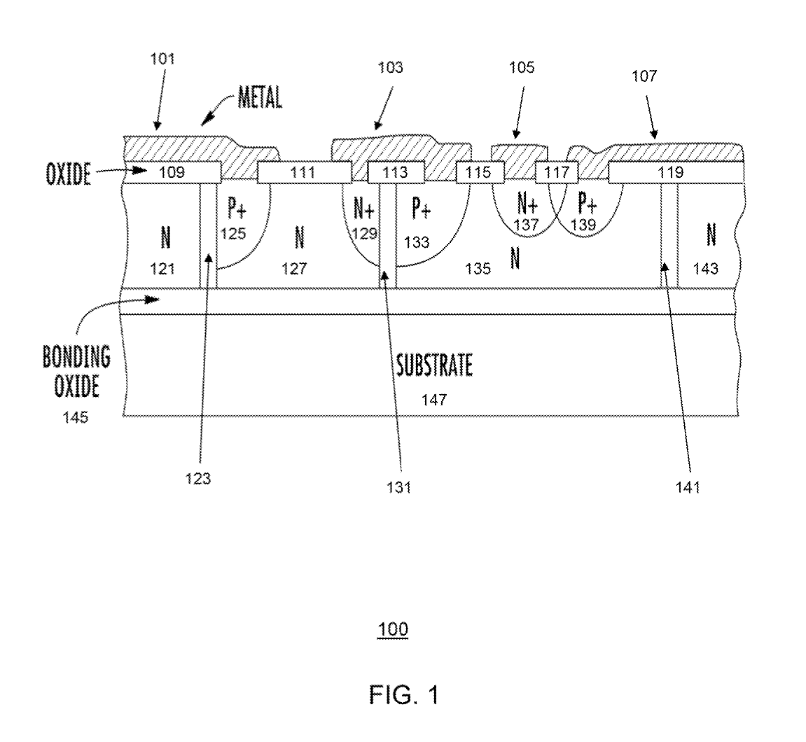

FIG. 1 shows a cross section of a dielectrically-isolated (DI) and silicon-on-insulator (SOI) electrical circuit protection chip structure (100) with a Zener diode (i.e. 137, 139) and steering diodes (i.e. 125, 127, 133, 135) connected monolithically in series, in accordance with an embodiment of the invention. In a preferred embodiment of the invention, a substrate layer comprising a plurality of semiconductor substrates and doped wells (121, 125, 127, 129, 133, 135, 137, 139, and 143) is electrically insulated from a bottom substrate (147) by a bonding oxide layer (145), thereby forming a silicon-on-insulator (SOI) configuration, as shown in FIG. 1.

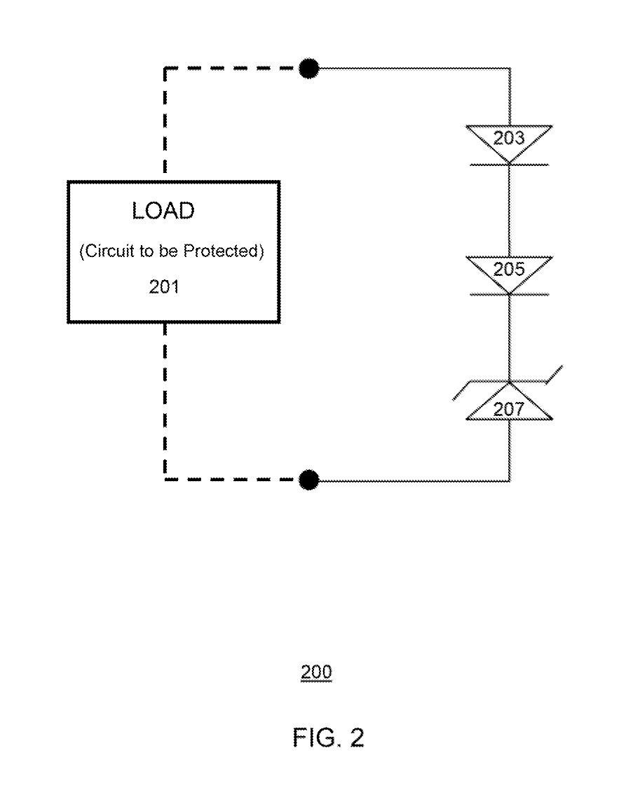

In a preferred embodiment of the invention, a first N-type bulk substrate (121) is electrically insulated laterally from a first doped P+ well (125) and a second N-type bulk substrate (127) by a first dielectrically-isolated wall (123) and the bonding oxide layer (145). Similarly, the first doped P+ well (125), the second N-type bulk substrate (127), and a first doped N+ well (129), which form a first PN diode (i.e. 203 of FIG. 2), are electrically insulated laterally by a second dielectrically-isolated wall (131) from an adjacent semiconductor structure (i.e. 133, 135, 137, 139), which forms a second PN diode (i.e. 133, 135, and 205 of FIG. 2) and a Zener diode (i.e. 137, 139, and 207 of FIG. 2). Likewise, the semiconductor structure (i.e. 133, 135, 137, 139), which forms the second PN diode (i.e. 133, 135, and 205 of FIG. 2) in series with the Zener diode (i.e. 137, 139, and 207 of FIG. 2), is also electrically insulated laterally from a fourth N-type bulk substrate (143) by a third dielectrically-isolated wall (141) and the bonding oxide layer (145).

Continuing with FIG. 1, a first metal interconnect (101) contacts the first doped P+ well (125) while being electrically insulated from other substrates by a first oxide strip (109) and a second oxide strip (111). Likewise, a second metal interconnect (103) contacts the first doped N+ well (129) and the second doped P+ well (133) to connect two PN diodes (the first PN diode (125, 127), the second PN diode (133, 135)) in series. The second metal interconnect (103) is electrically insulated from other substrates by the second oxide strip (111), a third oxide strip (113), and a fourth oxide strip (115). A third N-type bulk substrate (135) provides a series electrical connection between the second PN diode (133, 135) and the Zener diode (137, 139). In addition, a heat sink (105) contacts the second doped N+ well (137) to extract heat from the Zener diode structure (137, 139), wherein the heat sink (105) is electrically insulated from other substrates by the fourth oxide strip (115) and a fifth oxide strip (117). Furthermore, a third metal interconnect (107) contacts a third doped P+ well (139) for an electrical connection of the Zener diode (137, 139) to another electrical component not shown in FIG. 1, wherein the third metal interconnect (107) is electrically insulated from adjacent substrates by the fifth oxide strip (117) and a sixth oxide strip (119).

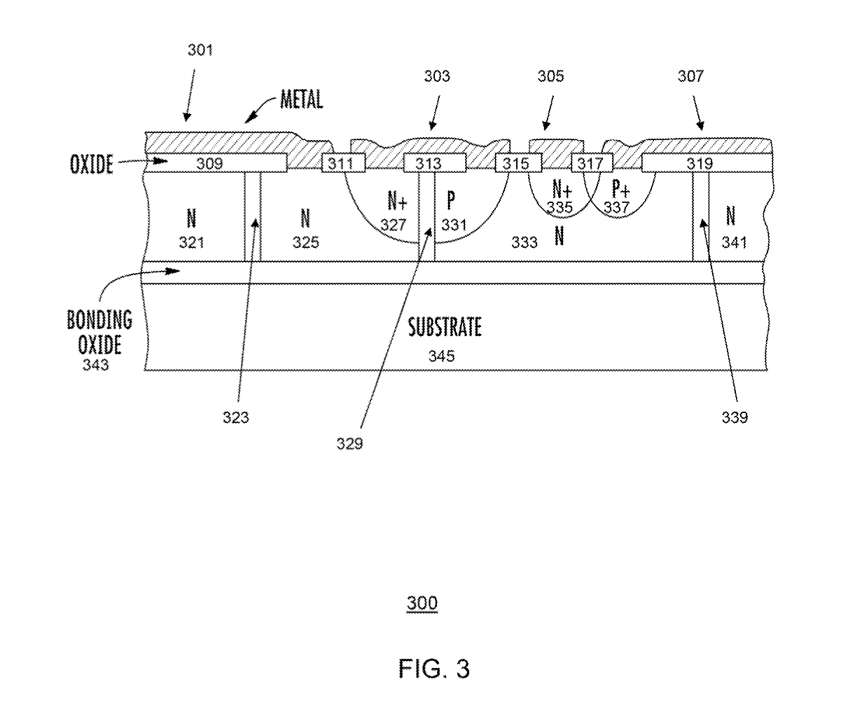

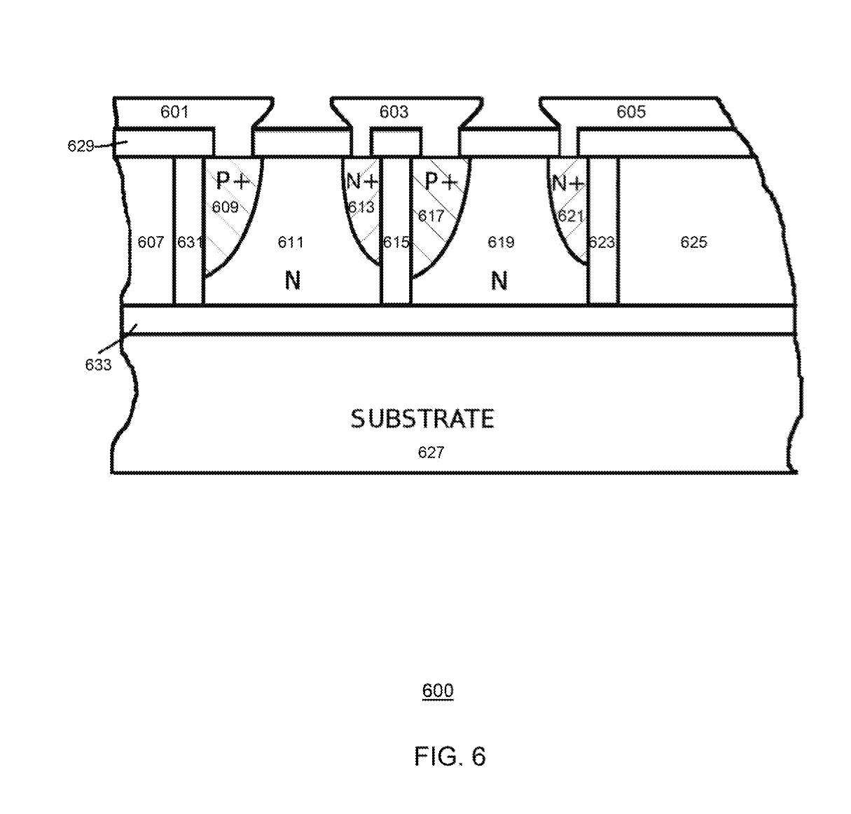

As shown in FIG. 1, the electrical circuit protection chip structure (100) utilizes dielectrically-isolated trenching (DI trenching) to provide sidewall electrical insulations (i.e. 123, 131, 141) as well as a silicon-on-insulator (SOI) configuration with the bonding oxide layer (145) to provide electrical insulation (i.e. 145) from the bottom substrate (147). This “silicon island” structure as disclosed in several embodiments of the present invention is novel and unique for an electrical circuit protection chip structure (e.g. 100 of FIG.1, 300 of FIG. 3, 600 of FIG. 6, and etc.). In context of FIG. 1, the first PN diode (125, 127) with the first doped N+ well (129) is a silicon island electrically insulated by two dielectrically-isolated sidewalls (123, 131) and the bonding oxide layer (145). Likewise, the second PN diode (133, 135) connected in series with the Zener diode (137, 139) forms another silicon island electrically insulated by two dielectrically-isolated sidewalls (131, 141) and the bonding oxide layer (145).

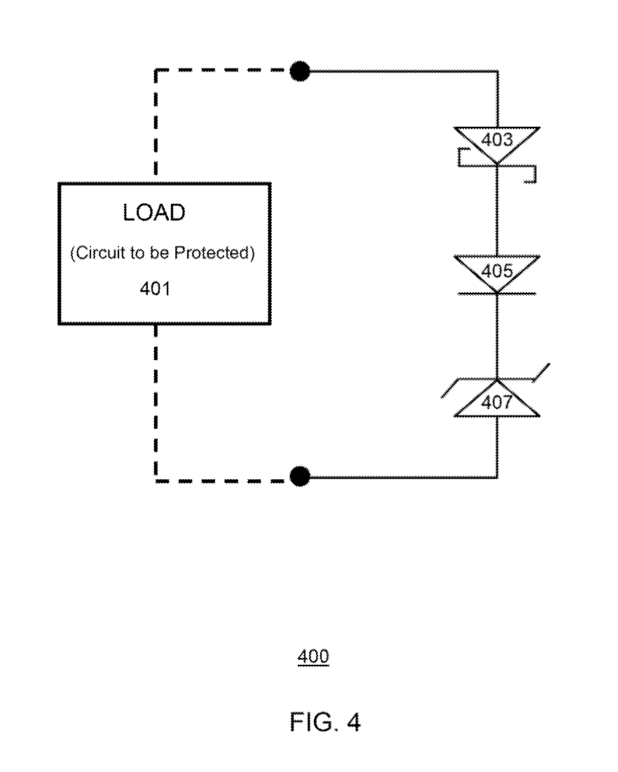

In various embodiments of the present invention, these silicon islands created by combining DI trenching and SOI methods uniquely enable monolithic series connections of silicon-based diode structures (i.e. in a single piece of chip structure), while significantly lowering device to substrate capacitances for a rapid and durable performance of voltage clamping and electrical circuit protection functions. In one embodiment of the invention, the monolithic series connections of silicon-based diode structures may involve a Zener diode connected in series with one or more steering diodes, wherein the breakdown voltage of the Zener diode provides a voltage clamping function, as shown in FIG. 1 and FIG. 2. In another embodiment of the invention the monolithic series connections of silicon-based diode structures may involve a Zener diode connected in series with a Shottky diode and a PN diode, wherein the Zener diode provides a voltage clamping function, as shown in FIG. 3 and FIG. 4. Yet in another embodiment of the invention, the monolithic series connections of silicon-based diode structures may involve a scalable number of forward-bias PN diodes connected in series, wherein each of the forward-bias PN diodes carry an individual forward-bias voltage, which add up for a total net clamping voltage value provided by the total number of forward-bias PN diodes connected in series.

FIG. 2 shows a circuit diagram (200) with a Zener diode (207) and steering diodes (203, 205) connected in series, which correspond to the novel electrical circuit protection chip structure (100) of FIG. 1, in accordance with an embodiment of the invention. In a preferred embodiment of the invention, the Zener diode (207) and the steering diodes (203, 205) are integrated monolithically in a single piece of chip structure, as exemplified by FIG. 1. In a typical power protection circuit application, an electrical load (i.e. a circuit to be protected) (201) is operatively connected to the electrical circuit protection circuitry (e.g. 203, 205, 207), which, at a minimum, provides a voltage clamping function to protect the electrical load (201) in a voltage spike event or another power surge event.

In one embodiment of the invention, as shown in FIG. 2, in case of a voltage spike event or another power surge event to the electrical load (201), the breakdown voltage of the Zener diode (207) serves as a clamping voltage value. In one example, the breakdown voltage of a Zener diode is 5.6 Volts. In another example, the breakdown voltage of a Zener diode may be higher or lower than 5.6 Volts.

FIG. 3 shows a cross section of a dielectrically-isolated (DI) and silicon-on-insulator (SOI) electrical circuit protection chip structure (300) with a Schottky diode (301, 325), a PN diode (331, 333), and a Zener diode (335, 337) connected monolithically in series, in accordance with an embodiment of the invention. In this embodiment of the invention, the monolithic series connections of silicon-based diode structures (i.e. 300) involves the Zener diode (335, 337) connected in series with the PN diode (331, 333) and the Shottky diode (301, 325), wherein the Zener diode (335, 337) provides a voltage clamping function, as shown in FIG. 4.

In the embodiment of the invention as shown in FIG. 3, a substrate layer comprising a plurality of semiconductor substrates and doped wells (321, 325, 327, 331, 333, 335, 337, and 341) is electrically insulated from a bottom substrate (345) by a bonding oxide layer (343), thereby forming a silicon-on-insulator (SOT) configuration, as shown in FIG. 3.

In a preferred embodiment of the invention, a first N-type bulk substrate (321) is electrically insulated laterally from a second N-type bulk substrate (325) by a first dielectrically-isolated wall (323) and the bonding oxide layer (343). Similarly, the second N-type bulk substrate (325) and a first doped N+ well (327), which form a Schottky diode with a metallic material (301) (i.e. 403 of FIG. 4), are electrically insulated laterally by a second dielectrically-isolated wall (329) from an adjacent semiconductor structure (i.e. 331, 333, 335, 337), which forms a PN diode (i.e. 331, 333, and 405 of FIG. 4) and a Zener diode (i.e. 335, 337, and 407 of FIG. 4). Likewise, the semiconductor structure (i.e. 331, 333, 335, 337), which forms the PN diode (i.e. 331, 333, and 405 of FIG. 4) in series with the Zener diode (i.e. 335, 337 and 407 of FIG. 4), is also electrically insulated laterally from a fourth N-type bulk substrate (341) by a third dielectrically-isolated wall (339) and the bonding oxide layer (343).

Continuing with FIG. 3, the metallic material (301) contacts the second N-type bulk substrate (325) while being electrically insulated from other substrates by a first oxide strip (309) and a second oxide strip (311). Likewise, a second metal interconnect (303) contacts the first doped N+ well (327) and the first P well (331) to connect the Schottky diode (301, 325) and the PN diode (331, 333) in series. The second metal interconnect (303) is electrically insulated from other substrates by the second oxide strip (311), a third oxide strip (313), and a fourth oxide strip (315). A third N-type bulk substrate (333) provides a series electrical connection between the PN diode (331, 333) and the Zener diode (335, 337).

In addition, a heat sink (305) contacts the second doped N+ well (335) to extract heat from the Zener diode structure (335, 337), wherein the heat sink (305) is electrically insulated from other substrates by the fourth oxide strip (315) and a fifth oxide strip (317). Furthermore, a third metal interconnect (307) contacts a doped P+ well (337) for an electrical connection of the Zener diode (335, 337) to another electrical component not shown in FIG. 3, wherein the third metal interconnect (307) is electrically insulated from adjacent substrates by the fifth oxide strip (317) and a sixth oxide strip (319).

As shown in FIG. 3, the electrical circuit protection chip structure (300) utilizes dielectrically-isolated trenching (DI trenching) to provide sidewall electrical insulations (i.e. 323, 329, 339) as well as a silicon-on-insulator (SOI) configuration with the bonding oxide layer (343) to provide electrical insulation (i.e. 343) from the bottom substrate (345). This “silicon island” structure as disclosed in several embodiments of the present invention is novel and unique for an electrical circuit protection chip structure (e.g. 100 of FIG.1, 300 of FIG. 3, 600 of FIG. 6, and etc.). In context of FIG. 3, the Schottky diode (301, 325) with the first doped N+ well (327) is a silicon island electrically insulated by two dielectrically-isolated sidewalls (323, 329) and the bonding oxide layer (343). Likewise, the PN diode (331, 333) connected in series with the Zener diode (335, 337) forms another silicon island electrically insulated by two dielectrically-isolated sidewalls (329, 339) and the bonding oxide layer (343).

FIG. 4 shows a circuit diagram (400) with a Schottky diode (403), a PN diode (405), and a Zener diode (407) connected in series, which correspond to the novel electrical circuit protection chip structure (300) of FIG. 3, in accordance with an embodiment of the invention. In this embodiment of the invention, the Zener diode (407), the Schottky diode (403), and the PN diode (405) are integrated monolithically in a single piece of chip structure, as exemplified by FIG. 3. In a typical power protection circuit application, an electrical load (i.e. a circuit to be protected) (401) is operatively connected to the electrical circuit protection circuitry (e.g. 403, 405, 407), which, at a minimum, provides a voltage clamping function to protect the electrical load (401) in a voltage spike event or another power surge event.

In one embodiment of the invention, as shown in FIG. 4, in case of a voltage spike event or another power surge event to the electrical load (401), the breakdown voltage of the Zener diode (407) serves as a clamping voltage value. In one example, the breakdown voltage of a Zener diode is 5.6 Volts. In another example, the breakdown voltage of a Zener diode may be higher or lower than 5.6 Volts.

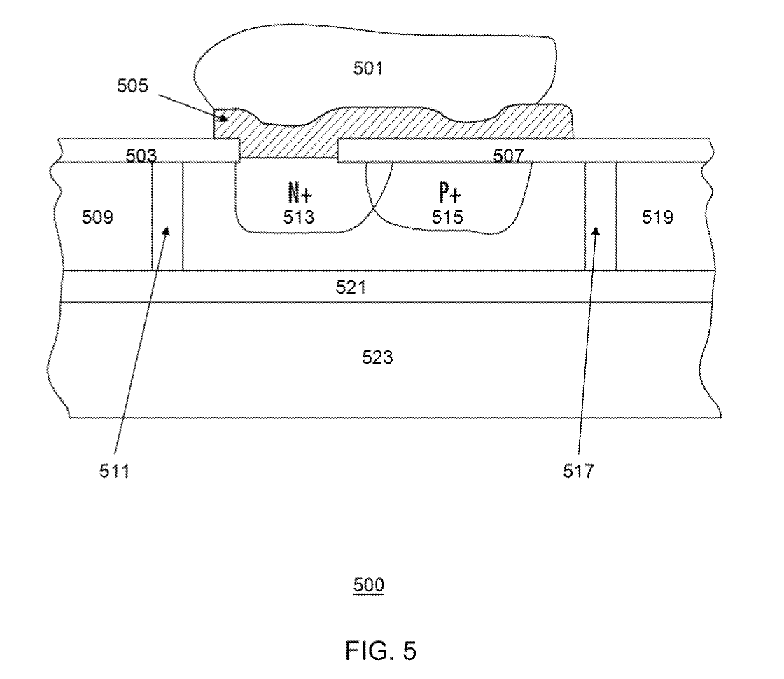

FIG. 5 shows a cross section of a dielectrically-isolated (DI) and silicon-on-insulator (SOI) chip structure (500) with a Zener diode (513, 515) and a top-surface heat sink (501), in accordance with an embodiment of the invention. In this embodiment of the invention, the Zener diode (513, 515) is immersed in an N-type bulk substrate, which is electrically insulated by a first dielectrically-isolated wall (511), a second dielectrically-isolated wall (517), and a bonding oxide (521) which insulates a semiconductor substrate layer (i.e. 509, 513, 515, 519) from a bottom substrate material (523). Laterally-adjacent bulk substrates (509, 519) are electrically insulated from the Zener diode (513, 515) by the dielectrically-isolated walls (511, 517). Furthermore, in this embodiment of the invention, a metal contact (505) attached to the top-surface heat sink (501) physically contacts a doped N+ well (513), wherein the metal contact (505) is electrically isolated from other semiconductor substrates by a first oxide strip (503) and a second oxide strip (507).

As shown in FIG. 5, for the dielectrically-isolated (DI and silicon-on-insulator (SOI) chip structure (500) with the Zener diode (513, 515) in one embodiment of the invention, it may be desirable to dissipate heat generated by the Zener diode (513, 515) to a top surface using the top-surface heat sink (501), which is thermally connected to the doped N+ well (513). In an SOI chip structure with the bonding oxide (521) and the bottom substrate (523), it may be difficult or undesirable to dissipate heat to the bottom side of the chip structure. Therefore, as shown in FIG. 5, in one or more embodiments of the invention, it may be desirable to provide an efficient thermal pathway to dissipate heat from a Zener diode or from another device structure by utilizing a top-surface heat sink (e.g. 501) and a metal contact (e.g. 505).

FIG. 6 shows a cross section of a dielectrically-isolated (DI) and silicon-on-insulator (SOI) electrical protection chip structure (600) with a scalable number of PN diodes (e.g. a first PN diode (609, 611), a second PN diode (617, 619), . . . , an n-th PN diode) connected monolithically in series, in accordance with an embodiment of the invention. In a preferred embodiment of the invention, a substrate layer comprising a plurality of semiconductor substrates and doped wells (607, 609, 611, 613, 617, 619, 621, and 625) is electrically insulated from a bottom substrate (627) by a bonding oxide layer (633), thereby forming a silicon-on-insulator (SOI) configuration, as shown in FIG. 6.

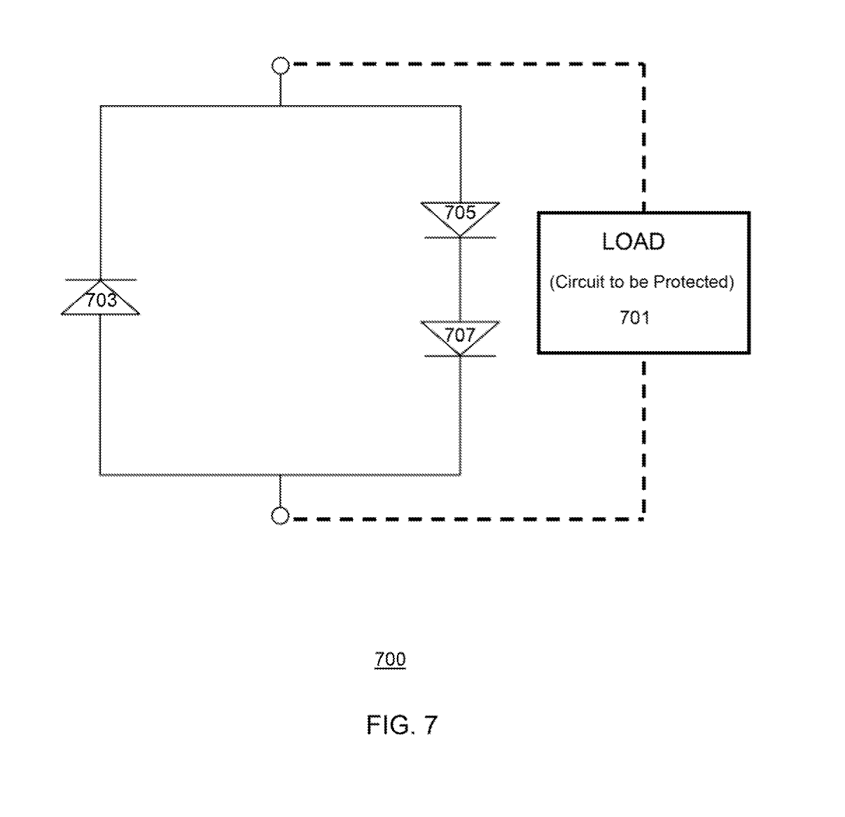

In a preferred embodiment of the invention, a first N-type bulk substrate (607) is electrically insulated laterally from a first doped P+ well (609) and a second N-type bulk substrate (611) by a first dielectrically-isolated wall (631) and the bonding oxide layer (633). Similarly, the first doped P+ well (609), the second N-type bulk substrate (611), and a first doped N+ well (613), which form a first PN diode (i.e. 609, 611, 705 of FIG. 7), are electrically insulated laterally by a second dielectrically-isolated wall (615) from an adjacent semiconductor structure (617, 619, 621), which forms a second PN diode (i.e. 617, 619, and 707 of FIG. 7). Likewise, the semiconductor structure (i.e. 617, 619, 621), which forms the second PN diode (i.e. 617, 619, and 707 of FIG. 7) in series with the first PN diode (i.e. 609, 611, and 705 of FIG. 7), is also electrically insulated laterally from a fourth N-type bulk substrate (625) by a third dielectrically-isolated wall (623) and the bonding oxide layer (633).

Continuing with FIG. 6, a first metal interconnect (601) contacts the first doped P+ well (609) while being electrically insulated from other substrates by one or more oxide strips (629). Likewise, a second metal interconnect (603) contacts the first doped N+ well (613) and the second doped P+ well (617) to connect two PN diodes (the first PN diode (609, 611), the second PN diode (617, 619)) in series. The second metal interconnect (603) is electrically insulated from other substrates by the one or more oxide strips (629). A third N-type bulk substrate (619) and a second doped N+ well (621) provide a series electrical connection between the second PN diode (617, 619) with another electrical component through a third metal interconnect (605).

In addition, in this embodiment of the invention as shown in FIG. 6, one or more metal contacts or metal interconnects (e.g. 601, 603, 605) can serve as heat dissipation pathways to extract heat from one or more PN diode structures (e.g. 609, 611, 613, 617, 619, 621) to the top surface.

As shown in FIG. 6, the electrical circuit protection chip structure (600) utilizes dielectrically-isolated trenching (DI trenching) to provide sidewall electrical insulations (i.e. 631, 615, 623) as well as a silicon-on-insulator (SOI) configuration with the bonding oxide layer (633) to provide electrical insulation (i.e. 633) from the bottom substrate (627). This “silicon island” structure as disclosed in several embodiments of the present invention is novel and unique for an electrical circuit protection chip structure (e.g. 100 of FIG.1, 300 of FIG. 3, 600 of FIG. 6, and etc.). In context of FIG. 6, the first PN diode (609, 611) with the first doped N+ well (613) is a silicon island electrically insulated by two dielectrically-isolated sidewalls (631, 615) and the bonding oxide layer (633). Likewise, the second PN diode (617, 619) connected in series with the first PN diode (609, 611) forms another silicon island electrically insulated by two dielectrically-isolated sidewalls (615, 623) and the bonding oxide layer (633).

Continuing with FIG. 6, in this embodiment of the invention, the monolithic series connections of PN diode structures enable a scalable number of forward-bias PN diodes connected in series. For this embodiment of the invention, each of the forward-bias PN diodes carry an individual forward-bias voltage, which adds up for a total net clamping voltage value provided by the total number of forward-bias PN diodes connected in series. Because a typical forward-bias voltage per PN diode is small (e.g. 0.5-0.6V per diode), designing an electrical protection circuit with a small clamping voltage value or a highly-customized clamping voltage value is made possible by the series connection scalability as disclosed in this embodiment of the invention.

Unlike some other embodiments of the invention in which a Zener diode is used to provide a clamping voltage, using a scalable number of forward-bias PN diodes enables a custom (i.e. scalable) design for a desirable clamping voltage for electrical circuit protection, compared to using a Zener diode with a substantially higher clamping voltage per Zener diode (e.g. 5.7 V breakdown voltage for a Zener diode). The scalability of the forward-bias diodes for a desirable clamping voltage as disclosed in FIG. 6 may be advantageous in some microelectronics designs, in which a clamping voltage provided by a typical Zener diode (e.g. 5.7V breakdown voltage) may not provide sufficient protection against voltage spikes that are lower than the breakdown voltage of the typical Zener diode, but still damaging to the electronic circuitry. Furthermore, by utilizing a scalable number of forward-bias diodes, an electrical circuit protection unit can exhibit a lower capacitance for a more rapid voltage clamping action in case of a power surge event. Moreover, the heat dissipation characteristics for the scalable number of series-connected forward-bias diodes in a monolithic chip are distributed among a multiple number of diodes, instead of being concentrated in a single “hot spot” around a Zener diode. Therefore, heat may be dissipated more efficiently if the scalable number of forward-bias diodes are utilized instead of a single Zener diode, as disclosed by this particular embodiment of the invention as shown in FIG. 6.

FIG. 7 shows a circuit diagram (700) with two forward-bias PN diodes (705, 707) connected in series and a reverse-polarity protection PN diode (703), in accordance with an embodiment of the invention. In a preferred embodiment of the invention, the two forward-bias PN diodes (705, 707) and the reverse-polarity protection PN diode (703) are integrated monolithically in a single piece of chip structure, as exemplified by FIG. 6. In a typical power protection circuit application, an electrical load (i.e. a circuit to be protected) (701) is operatively connected to the electrical circuit protection circuitry (e.g. 705, 707, 703), which, at a minimum, provides a voltage clamping function to protect the electrical load (701) in a voltage spike event or another power surge event.

In one embodiment of the invention, as shown in FIG. 7, in case of a voltage spike event or another power surge event to the electrical load (701), an addition of all forward-bias voltages for each PN diode (705, 707) serves as a net clamping voltage. Because a typical forward-bias voltage of each PN diode is merely 0.5˜0.6 V per diode, it is possible to design an electrical protection circuit with a net clamping voltage well under a 5.6 Volts, which is a typical clamping voltage value if a Zener diode (i.e. with a breakdown voltage of 5.6 Volts) is used instead. As discussed previously in association with FIG. 6, the scalability of the forward-bias diodes for a desirable clamping voltage as described in FIG. 6 and FIG. 7 can provide a lower capacitance for a fast voltage clamping, a more thermally-efficient distributed heat dissipation pathway, and a more sensitive protection against smaller-magnitude voltage spikes than a comparable Zener diode-based design.

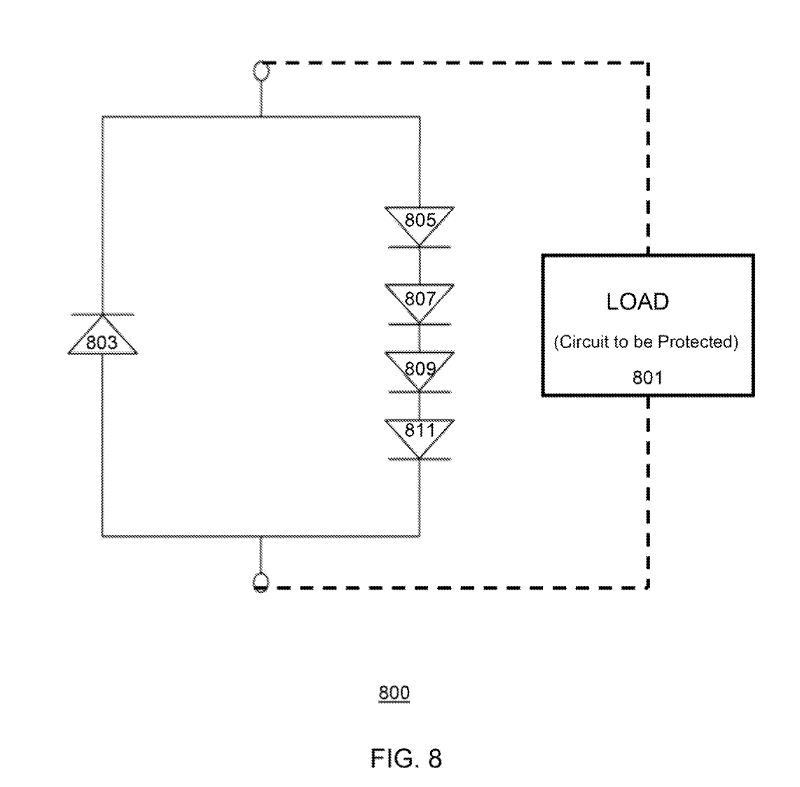

FIG. 8 shows a circuit diagram (800) with four forward-bias PN diodes (805, 807, 809, and 811) connected in series and a reverse-polarity protection PN diode (803), in accordance with an embodiment of the invention. In a preferred embodiment of the invention, the four forward-bias PN diodes (805, 807, 809, and 811) and the reverse-polarity protection PN diode (803) are integrated monolithically in a single piece of chip structure, as exemplified by FIG. 6. In a typical power protection circuit application, an electrical load (i.e. a circuit to be protected) (801) is operatively connected to the electrical circuit protection circuitry (e.g. 805, 807, 809, 811, 803), which, at a minimum, provides a voltage clamping function to protect the electrical load (801) in a voltage spike event or another power surge event.

As shown by two additional forward-bias PN diodes (e.g. 809, 811) in FIG. 8 compared to the two forward-bias PN diode design shown in FIG. 7, the number of forward-bias PN diodes connected in series can be scalable in accordance with a desirable clamping voltage value. In one embodiment of the invention, as shown in FIG. 8, in case of a voltage spike event or another power surge event to the electrical load (801), an addition of all forward-bias voltages for each PN diode (805, 807, 809, 811) serves as a net clamping voltage. Because a typical forward-bias voltage of each PN diode is merely 0.5˜0.6 V per diode, it is possible to design an electrical protection circuit with a net clamping voltage well under a 5.6 Volts, which is a typical clamping voltage value if a Zener diode (i.e. with a breakdown voltage of 5.6 Volts) is used instead. As discussed previously in association with FIG. 6 and FIG. 7, the scalability of the forward-bias diodes for a desirable clamping voltage as described in FIGS. 6˜8 can provide a lower capacitance for a fast voltage clamping, a more thermally-efficient distributed heat dissipation pathway, and a more sensitive protection against smaller-magnitude voltage spikes than a comparable Zener diode-based design.

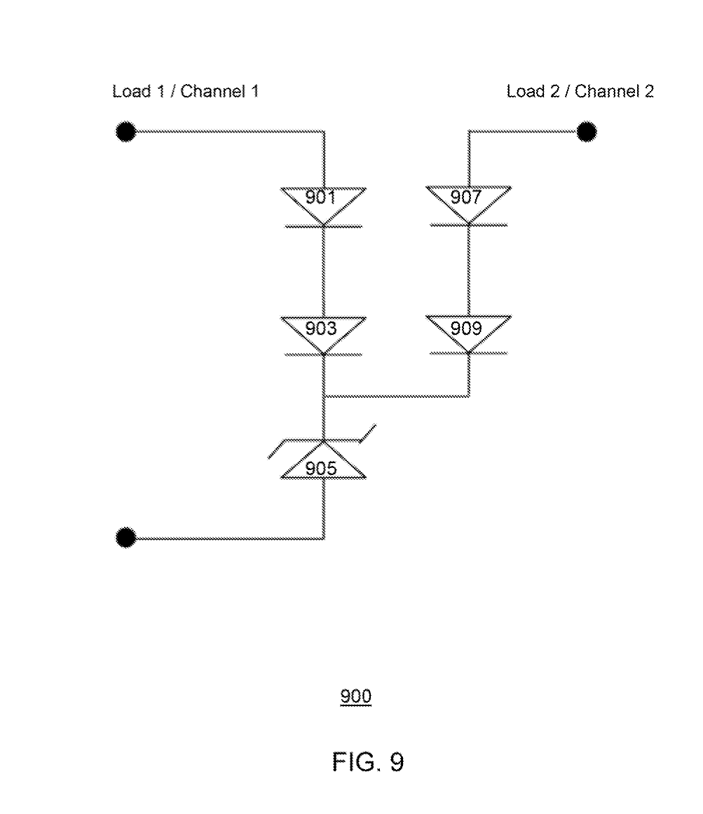

FIG. 9 shows a circuit diagram for a multi-channel electrical protection configuration (900) with a Zener diode (905) and multiple sets of steering diodes (901 and 903, or 907 and 909) connected in series, in accordance with an embodiment of the invention. In one embodiment of the multiple-channel electrical protection configuration (900) as shown in FIG. 9, a first plurality of series PN diodes (901, 903) comprises a first set of steering diodes, which are connected in series with the Zener diode (905). This first plurality of series PN diodes (901, 903) connected in series with the Zener diode (905) provides electrical protection contact terminals for a first load (i.e. “Channel 1” in FIG. 9) electrical protection.

Likewise, in the embodiment of the multiple-channel electrical protection configuration (900) as shown in FIG. 9, a second plurality of series PN diodes (907, 909) comprises a second set of steering diodes, which are connected in series with the Zener diode (905). This second plurality of series PN diodes (907, 909) connected in series with the Zener diode (905) provides electrical protection contact terminals for a second load (i.e. “Channel 2” in FIG. 9) electrical protection. In one embodiment of the invention, this multiple-channel electrical protection configuration (900) as shown in FIG. 9 may be cascaded further to protect any number of desirable channels (i.e. three, four, five channel electrical circuit protections, and etc.) as envisioned by an electrical protection circuit designer.

In one embodiment of the invention, a single set (901 and 903, or 907 and 909) of plurality of series PN diodes connected in series with the Zener diode (905) corresponds to the novel electrical circuit protection chip structure (100) of FIG. 1, in accordance with an embodiment of the invention. In a preferred embodiment of the invention, the Zener diode (905) and at least one set (901 and 903, or 907 and 909) of the plurality of series PN diodes are integrated monolithically in a single piece of chip structure.

Furthermore, for this multi-channel electrical protection configuration (900) as shown in FIG. 9, electrical loads (i.e. “Load 1” and/or “Load 2”) operatively connected to “Channel 1” and/or “Channel 2” terminals are protected from undesirable voltage surge events or another power surge events via a voltage clamping function provided by the Zener diode (905). In one embodiment of the invention, as shown in FIG. 9, in case of a voltage spike event or another power surge event to one or more electrical loads, the breakdown voltage of the Zener diode (905) serves as a clamping voltage value. In one example, the breakdown voltage of a Zener diode is 5.6 Volts. In another example, the breakdown voltage of a Zener diode may be higher or lower than 5.6 Volts.

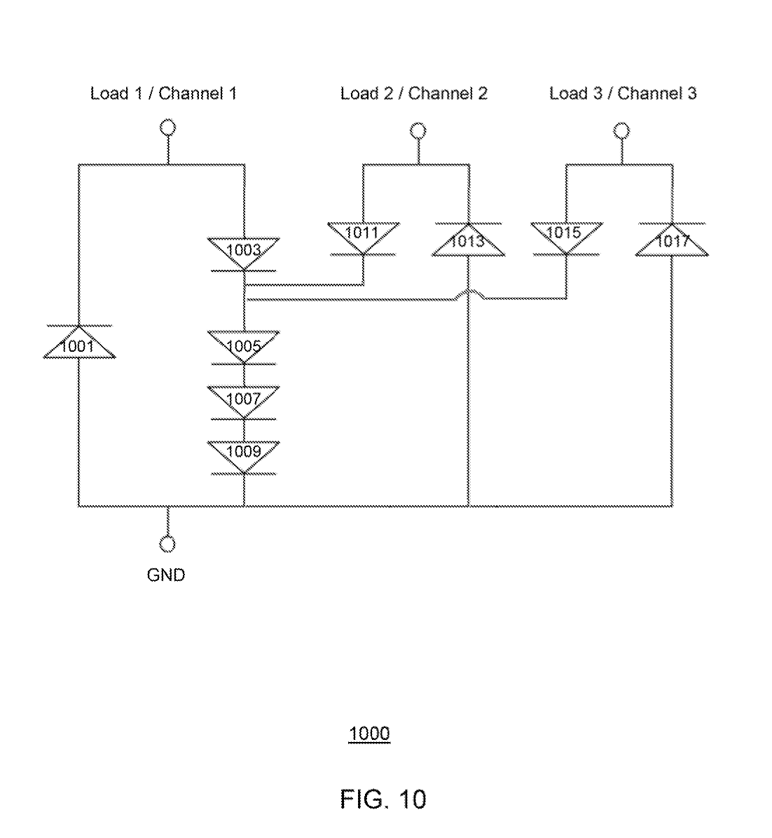

FIG. 10 shows a circuit diagram for a cascaded multi-channel electrical protection configuration (1000) with three overlapping sets of forward-bias PN diodes connected in series (1005, 1007, and 1009 with 1003, 1011, or 1015) and corresponding reverse-polarity protection PN diodes (1001, 1013, 1017), in accordance with an embodiment of the invention. In this particular cascaded multi-channel electrical protection configuration (1000), three separate loads (i.e. Load 1, Load 2, Load 3), each of which requiring electrical protection, can be connected to three corresponding channels (i.e. Channel 1, Channel 2, Channel 3) of the cascaded multi-channel electrical protection configuration (1000) as shown in FIG. 10. In this embodiment of the invention, Channel 1 comprises four forward-bias PN diodes (1003, 1005, 1007, and 1009) connected with a first corresponding reverse-polarity protection PN diode (1001). Likewise, Channel 2 comprises four forward-bias PN diodes (1011, 1005, 1007, 1009) connected with a second corresponding reverse-polarity protection PN diode (1013). Similarly, Channel 3 comprises four forward-bias PN diodes (1015, 1005, 1007, 1009) connected with a third corresponding reverse-polarity protection PN diode (1017).

In one embodiment of the invention, the number of channels attached to the cascaded multi-channel electrical protection configuration (1000) is scalable and may vary, depending on a particular design of a multi-channel electrical protection circuit. Furthermore, in one embodiment of the invention, a multiple number of channels may share a common ground node (GND), as shown in FIG. 10, or utilize other electrical contacts as desired.

In a preferred embodiment of the invention, at least one set among the three overlapping sets of forward-bias PN diodes connected in series (i.e. 1005, 1007, and 1009 with 1003, 1011, or 1015) and at least one of the corresponding reverse-polarity protection PN diodes (1001, 1013, 1017) are integrated monolithically in a single piece of chip structure, as exemplified by FIG. 6. In a typical multi-channel electrical protection configuration (1000), an electrical load connected to each channel is protected from a voltage spike event or another power surge event with a voltage clamping function achieved by the scalable number of forward-bias PN diodes connected in series (i.e. 1005, 1007, and 1009 with 1003, 1011, or 1015).

One or more embodiments of the power protection system and the related method has been illustrated in FIGS. 110 and described above. The present invention provides numerous advantages over conventional power protection designs. For example, one or more embodiments of the present invention uniquely enables a fast, low junction capacitance, small footprint, and thermally-efficient electrical circuit protection design by utilizing dielectrically-isolated (DI) sidewalls and silicon-on-insulator (SOI) technology. The unique and novel utilization of DI trenches and SOI in electrical circuit protection designs enables monolithic integration and series connection of a plurality of diodes in a single piece of a substrate structure.

Furthermore, one or more embodiments of the present invention also provides an advantage of providing a customizable clamping voltage value by utilizing a scalable number of forward-bias diodes, which are monolithically connected in series. In these embodiments of the invention, the scalability of the forward-bias diodes for a desirable clamping voltage can provide an additional benefit of even lower capacitance for a fast voltage clamping, a higher thermal efficiency, and a higher sensitivity protection against smaller-magnitude voltage spikes than a comparable Zener diode-based design.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An electrical circuit protection device incorporating diodes in a single piece of semiconductor substrates, the electrical circuit protection device comprising:
a bottom substrate layer;
a bonding oxide layer electrically insulating the bottom substrate layer from the semiconductor substrates positioned above the bonding oxide layer;
the semiconductor substrates comprising one or more silicon islands, wherein each silicon island is electrically insulated by one or more dielectrically-isolated sidewalls and the bonding oxide layer on a bottom surface of each silicon island;
the one or more silicon islands, each of which containing an N-type bulk substrate and one, or more silicon wells forming a PN diode and/or a Zener diode in each silicon island;
one or more metal interconnects physically contacting the one or more silicon wells to provide one or more monolithic series connections among the diodes; and
one or more oxide strips underneath the one or more metal interconnects to provide necessary electrical insulation between the one or more metal interconnects and the semiconductor substrates outside of physical contact regions.

2. The electrical circuit protection device of claim 1, wherein the one or more silicon wells are doped or undoped p-wells or n-wells.

3. The electrical circuit protection device of claim 1, wherein the one or more silicon islands include a doped N+ well partially overlapping a doped P+ well, which form the Zener diode.

4. The electrical circuit protection device of claim 1, wherein the one or more silicon islands include a doped P+ well next to the N-type bulk substrate to form the PN diode.

5. The electrical circuit protection device of claim 1, wherein one of the one or more metal interconnects has a first end contacting a first silicon well in a first silicon island containing a first diode, and also has a second end contacting a second silicon well in a second silicon island containing a second diode to form series connection of the first diode and the second diode monolithically on the single piece of semiconductor substrates.

6. The electrical circuit protection device of claim 1, wherein the Zener diode in at least one silicon island provides a clamping voltage corresponding to a breakdown voltage of the Zener diode in case of a voltage spike or another power surge event in the electrical circuit protection device.

7. The electrical circuit protection device of claim 1, wherein the one or more silicon islands contain a plurality of forward-bias PN diodes connected in series without any Zener diodes, wherein the plurality of forward-bias PN diodes provide a net clamping voltage as a summation of each forward-bias PN diode in case of a voltage spike or another power surge event in the electrical circuit protection device.

8. The electrical circuit protection device of claim 1, wherein one of the one or more silicon islands has a heat sink placed on top of a metal contact, which touches a surface of the one or more silicon wells for efficient heat dissipation.

9. The electrical circuit protection device of claim 1, wherein the diodes also include a Schottky diode connected in series with the PN diode and/or the Zener diode.

10. The electrical circuit protection device of claim 1, wherein the electrical circuit protection device also includes a reverse-polarity protection PN diode.

11. An electrical circuit protection device incorporating diodes in a single piece of semiconductor substrates, the electrical circuit protection device comprising:
a bottom substrate layer;
a bonding oxide layer electrically insulating the bottom substrate layer from the semiconductor substrates positioned above the bonding oxide layer;
the semiconductor substrates comprising one or more silicon islands, wherein each silicon island is electrically insulated by one or more dielectrically-isolated sidewalls and the bonding oxide layer on a bottom surface of each silicon island;
the one or more silicon islands, each of which containing an N-type bulk substrate and a doped P+ well to form at least one forward-bias PN diode per silicon island, wherein a plurality of forward-bias PN diodes formed by the one or more silicon islands is monolithically connected in series using one or more metal interconnects;
the one or more metal interconnects, each of which physically contacting a first region of the one or more silicon islands and a second region of the one or more silicon islands to provide one or more monolithic series connections among the diodes; and
one or more oxide strips underneath the one or more metal interconnects to provide necessary electrical insulation between the one or more metal interconnects and the semiconductor substrates outside of physical contact regions.

12. The electrical circuit protection device of claim 11, wherein the plurality of forward-bias PN diodes formed by the one or more silicon islands provides a net clamping voltage as a summation of each forward-bias PN diode in case of a voltage spike or another power surge event in the electrical circuit protection device.

13. The electrical circuit protection device of claim 11, wherein a particular silicon island among the one or more silicon islands has a heat sink placed on top of a metal contact, which touches a portion of a top surface of the particular silicon island for efficient heat dissipation.

14. The electrical circuit protection device of claim 11, wherein the electrical circuit protection device also includes a reverse-polarity protection PN diode.
